(19) United States
(12) Patent Application Publication
(10) Pub. No.: US 2023/0329037 A1
(43) Pub. Date: Oct. 12, 2023

(54) DISPLAY BASE PLATE AND METHOD FOR MANUFACTURING THE SAME, AND DISPLAY PANEL

(71) Applicant: BOE TECHNOLOGY GROUP CO., LTD., Beijing (CN)

(72) Inventors: Meng Zhao, Beijing (CN); Feng Guan, Beijing (CN); Wei Liu, Beijing (CN); Fengjuan Liu, Beijing (CN); Lubin Shi, Beijing (CN); Ce Ning, Beijing (CN)

(73) Assignee: BOE TECHNOLOGY GROUP CO., LTD., Beijing (CN)

(21) Appl. No.: 18/022,924

(22) PCT Filed: Mar. 4, 2022
(86) PCT No.: PCT/CN2022/079199

§ 371 Date: Feb. 23, 2023

(30) Foreign Application Priority Data
Jun. 23, 2021 (CN) 202110700542.X

(51) Int. Cl. H10K 59/121; H10K 59/131; H10K 59/12

(52) U.S. Cl. CPC H10K 59/1213; H10K 59/131; H10K 59/1201; H10K 59/1216

(57) ABSTRACT

A display base plate, a preparation method therefor and a display panel are provided in the present disclosure. The display panel can greatly improve resolution while ensuring low power consumption. The display base plate includes a plurality of sub-pixels. Each of the plurality of sub-pixels includes a storage capacitor, a polysilicon transistor and at least one oxide transistor. The storage capacitor includes a first electrode and a second electrode oppositely arranged, and first electrode is arranged at a side of the second electrode away from the substrate. The second electrode is arranged in the same layer as a gate electrode of the polysilicon transistor. The at least one oxide transistor is arranged on a side of the first electrode away from the substrate, and the first electrode at least partially overlaps with an active layer of the at least one oxide transistor in a direction perpendicular to the substrate.

### CROSS-REFERENCES TO RELATED APPLICATIONS

The present disclosure claims the priority of the Chinese patent application filed on Jun. 23, 2021 before the CNIPA, China National Intellectual Property Administration with the application number of 202110700542.X and the title of “DISPLAY SUBSTRATE AND PREPARATION METHOD THEREFOR, AND DISPLAY PANEL”, which is incorporated herein in its entirety by reference.

### TECHNICAL FIELD

The present disclosure relates to the technical field of displaying and, more particularly, to a display base plate, a preparation method therefor and a display panel.

### BACKGROUND

An organic light-emitting diode (OLED) display has gradually become a mainstream in the displaying field due to its excellent performance such as low power consumption, high color saturation, a wide viewing angle, a thin thickness and flexibility, which can be widely used in smart phones, tablet computers, televisions and other terminal products.

Currently, a LTPO backplane driving circuit, that is, a backplane structure combining a low temperature polysilicon thin film transistor (LTPS-TFT) and an oxide thin film transistor (oxide-TFT), is generally adopted in wearable devices (such as smart watches). In this structure, the LTPS-TFT serves as a driving TFT of an OLED element, and the oxide-TFT serves as a switching TFT. Characteristics of the LTPS-TFT, such as a fast response speed and a large turn-on current, are utilized to provide a current source for OLED displaying. Meanwhile, a low leakage characteristic of the oxide-TFT is utilized to reduce power consumption of the backplane. This low power consumption design is more suitable for the wearable devices.

However, in LTPO technologies, a size of the oxide-TFT is large; and meanwhile the oxide-TFT is a NMOS transistor while the LTPS-TFT is a PMOS transistor, with different driving voltages, which leads to dense wiring of a LTPO backplane, and finally it is difficult to form a high-resolution display panel.

### SUMMARY

A display base plate, a preparation method therefor and a display panel are provided in an embodiment of the disclosure, which can greatly improve a resolution while ensuring low power consumption.

In order to achieve above objects, embodiments of the disclosure incorporate following technical solutions.

In an aspect, a display base plate is provided, which includes a substrate and a plurality of sub-pixels arranged in an array at a side of the substrate.

Each of the plurality of sub-pixels includes a storage capacitor, a polysilicon transistor and at least one oxide transistor. The storage capacitor includes a first electrode and a second electrode oppositely arranged, and the first electrode is arranged at a side of the second electrode away from the substrate.

The second electrode is arranged in a same layer as a gate electrode of the polysilicon transistor. The at least one oxide transistor is arranged on a side of the first electrode away from the substrate, and the first electrode at least partially overlaps with an active layer of the at least one oxide transistor in a direction perpendicular to the substrate.

The first electrode is configured to access a power signal and also serves as a bottom gate of an overlapping oxide transistor. An oxide transistor at least partially overlapping with the first electrode in the direction perpendicular to the substrate is the overlapping oxide transistor.

Optionally, an orthographic projection of the active layer of the at least one of the oxide transistors on the substrate is located within an orthographic projection of the first electrode on the substrate.

Optionally, an orthographic projection of the second electrode on the substrate is located within the orthographic projection of the first electrode on the substrate.

Optionally, the display base plate further includes a power line, and the first electrode is electrically connected to the power line.

Optionally, the power line is arranged in the same layer as a first electrode and a second electrode of the overlapping oxide transistor.

Optionally, the polysilicon transistor is a top-gate polysilicon transistor, and the active layer of the polysilicon transistor is arranged between the substrate and the gate electrode of the polysilicon transistor.

Optionally, a first electrode and a second electrode of the polysilicon transistor are arranged in the same layer as a first electrode and a second electrode of the overlapping oxide transistor.

Optionally, the sub-pixel further includes an anode, and either the first electrode or the second electrode of the polysilicon transistor is electrically connected to the anode.

Optionally, the polysilicon transistor is a P-type transistor and the oxide transistor is an N-type transistor.

Optionally, the sub-pixel further includes a single-gate oxide transistor, and an active layer of the single-gate oxide transistor does not overlap with the first electrode in the direction perpendicular to the substrate.

Optionally, the sub-pixel further includes a first transistor, a second transistor, a third transistor, a fourth transistor, a fifth transistor, a sixth transistor and a seventh transistor; and the first transistor and the second transistor are the oxide transistors and the third transistor is the polysilicon transistor;
the display base plate further includes a power line, a light-emitting control signal line, a data signal line, a reset control signal line and an initial signal line; and the sub-pixel further includes a light-emitting diode;
a gate electrode of the first transistor is electrically connected to the reset control signal line, a second electrode of the first transistor is electrically connected to the initial signal line, a first electrode of the first transistor and a first electrode of the second transistor are electrically connected to a first node, a gate electrode of the third transistor and a second electrode of the storage capacitor are electrically connected to the first node, and a first electrode of the storage capacitor is electrically connected to the power line;
a gate electrode of the second transistor is electrically connected to the reset control signal line, and a second electrode of the second transistor is electrically connected to a third node, a first electrode of the third transistor is electrically connected to a second node, and a second electrode of the third transistor is electrically connected to the third node, a first electrode of the fourth transistor is electrically connected to the second node, the second electrode of the fourth transistor is electrically connected to the data signal line, a gate electrode of the fourth transistor is electrically connected to the reset control signal line, a second electrode of the fifth transistor is electrically connected to the second node, a first electrode of the fifth transistor is electrically connected to the power line, and a gate electrode of the fifth transistor is electrically connected to the light-emitting control signal line; and
a gate electrode of the sixth transistor is electrically connected to the light-emitting control signal line, a first electrode of the sixth transistor is electrically connected to the third node, and the second electrode of the sixth transistor is electrically connected to a fourth node, a gate electrode of the seventh transistor is electrically connected to the reset control signal line, a first electrode of the seventh transistor is electrically connected to the fourth node, and a second electrode of the seventh transistor is electrically connected to the initial signal line, an anode of the light-emitting diode is electrically connected to the fourth node, and a cathode of the light-emitting diode is connected to ground;
wherein orthographic projections of active layers of the first transistor and the second transistor on the substrate are both located within an orthographic projection of the first electrode on the substrate, and orthographic projections of active layers of other transistors on the substrate do not overlap with the orthographic projection of the first electrode on the substrate.

In another aspect, a display panel is provided, including the display base plate stated above.

In yet another aspect, a method for manufacturing a display base plate stated above is provided, including:
forming the plurality of sub-pixels arranged in the array on the substrate;
wherein forming the plurality of sub-pixels arranged in the array on the substrate includes:
forming the storage capacitor, the polysilicon transistor and at least one oxide transistor;
wherein the storage capacitor includes the first electrode and the second electrode oppositely arranged, the first electrode is arranged at the side of the second electrode away from the substrate, the second electrode is arranged in the same layer as the gate electrode of the polysilicon transistor; the at least one oxide transistor is arranged on the side of the first electrode away from the substrate, and the first electrode at least partially overlaps with the active layer of the at least one oxide transistor in the direction perpendicular to the substrate; and the first electrode is configured to access the power signal and further serves as the bottom gate of the overlapping oxide transistor, wherein the oxide transistor at least partially overlapping with the first electrode in the direction perpendicular to the substrate is the overlapping oxide transistor.

Optionally, forming the storage capacitor and the polysilicon transistor includes:

forming a second electrode of the storage capacitor and a gate electrode of the polysilicon transistor by using one-step patterning process.

Optionally, forming the polysilicon transistor and the overlapping oxide transistor includes:

forming a first electrode and a second electrode of the polysilicon transistor and a first electrode and a second electrode of the overlapping oxide transistor by using one-step patterning process.

The above description is only a summary of the technical solution of the present disclosure, which can be implemented according to the contents of the description in order to understand the technical means of the present disclosure more clearly. In order to make the above and other objects, features and advantages of the present disclosure more obvious and understandable, the following is a specific embodiment of the present disclosure.

### BRIEF DESCRIPTION OF THE DRAWINGS

In order to explain the embodiments of the present disclosure or the technical solution in the related art more clearly, the drawings required in the description of the embodiments or the prior art will be briefly introduced below; obviously, the drawings in the following description are only some embodiments of the present disclosure, and other drawings can be obtained according to these drawings by those of ordinary skill in the art without paying creative labor.

FIG. 1 is a schematic structural diagram of an LTPO base plate according to an embodiment of the present disclosure;

FIG. 2 is a circuit diagram of a 7T1C according to an embodiment of the present disclosure;

FIG. 3 is a 7T1C layout by using a structure of FIG. 1;

FIG. 4 is a schematic structural diagram of a display base plate according to an embodiment of the present disclosure;

FIG. 5 is a 7T1C layout by using a structure of FIG. 4;

FIGS. 6 to 13 are flow charts for preparing a structure of FIG. 13 according to an embodiment of the present disclosure;

FIG. 14 is a schematic structural diagram of another display base plate according to an embodiment of the present disclosure;

FIG. 15 is a schematic diagram of a test structure of a display base plate according to an embodiment of the present disclosure; and

FIG. 16 is an equivalent structural diagram of FIG. 15.

### DETAILED DESCRIPTION OF THE EMBODIMENTS

In the following, the technical solution in the embodiment of the disclosure will be described clearly and completely in connection with the drawings; obviously, the described embodiment is intended to be only a part of the embodiment of the disclosure, but not all of them. On a basis of the embodiments in the present disclosure, all other embodiments obtained by the ordinary skilled in the art without any creative effort should be within a protection scope of the present disclosure.

In embodiments of the present disclosure, words “first”, “second”, . . . , “seventh” are used to distinguish the same items or similar items with substantially same functions and purposes, only to clearly describe technical solutions of the embodiments of the present disclosure, but cannot be understood as indicating or implying relative importance or implicitly indicating a number of indicated technical features.

In an embodiment of the present disclosure, meaning of “a plurality of” is two or more, and meaning of “at least one” is one or more, unless otherwise specifically defined.

In the embodiment of the present disclosure, an orientation or positional relationship indicated by the terms “upper” and “lower” is based on orientation or positional relationships shown in the drawings, and are merely for convenience of describing the present disclosure and simplifying the description, rather than indicate or imply that the device or element referred to must have a specific orientation, be configured and operated in a specific orientation, and thus cannot be understood as a limitation on the present disclosure.

In an embodiment of the present disclosure, a transistor includes a gate electrode, a source electrode and a drain electrode, and one of the source electrode and the drain electrode is called a first electrode and the other of the source electrode and the drain electrode is called a second electrode.

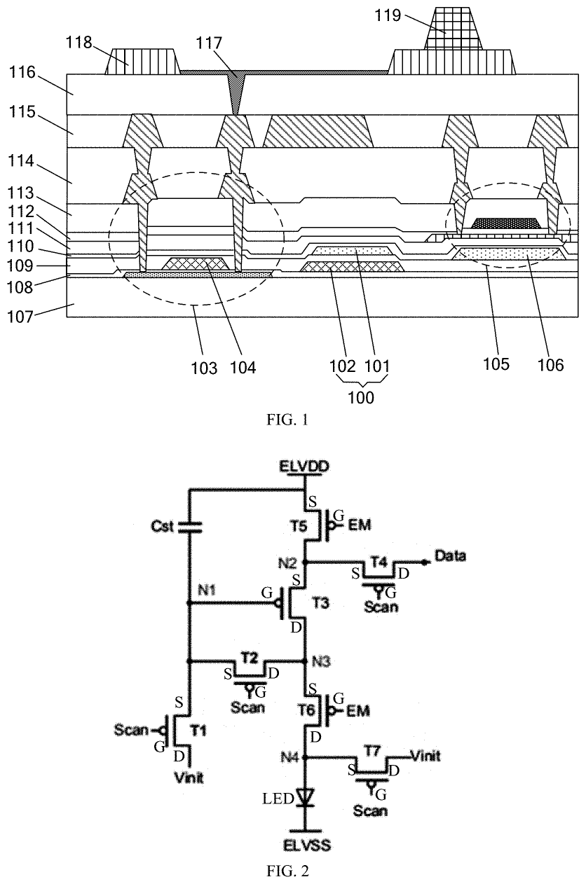

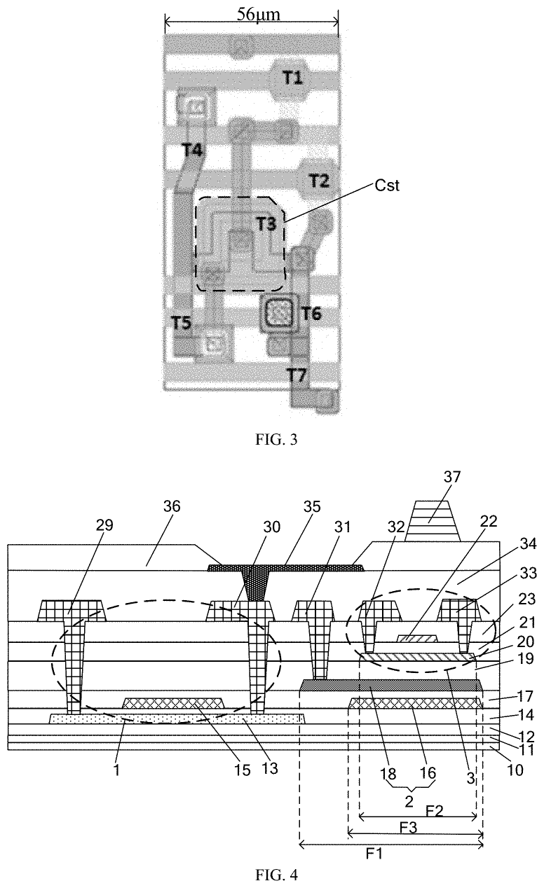

In related art, an LTPO base plate may include an LTPS driving transistor 103, an oxide switching transistor 105 and a capacitor Cst 100 as shown in FIG. 1. The LTPS driving transistor and the oxide switching transistor are disposed in parallel, the oxide switching transistor is a double-gate transistor, a gate electrode 104 of the LTPS driving transistor 103 and a second electrode 102 of the capacitor Cst 100 are disposed in a same layer, and a first electrode 101 of the capacitor Cst 100 and a bottom gate 105 of the oxide switching transistor 105 are disposed in a same layer. In FIG. 1, the LTPO base plate further includes a PI (polyimide) substrate 107, a first GI layer 108, a first ILD layer 109, a second ILD layer 110, a buffer layer 111, a second GI layer 112, a second ILD layer 113, a first PLN layer 114, a second PLN layer 115, an anode layer 117, a PDL layer 118, and a PS layer 119, a structure of which may be made with 13 masks. A 7T1C driving circuit as shown in FIG. 2 may be adopted in the LTPO base plate, in which the LTPS driving transistor as shown in FIG. 1 may be taken as the transistor T3, and the transistors T1 and T2 may be taken as the oxide switching transistor as shown in FIG. 1. A layout of the 7T1C driving circuit may be shown in FIG. 3, and a pitch (spacing) of a finally formed sub-pixel is 56 μm, and a corresponding PPI (Pixels Per Inch) is about 450. By using an LTPS technologies, the PPI can reach 630. The PPI of LTPO panel needs to be further improved.

Based on the above, a display base plate is provided in an embodiment of the present disclosure, which includes a substrate and a plurality of sub-pixels arranged in an array at a side of the substrate.

Referring to FIG. 4, a sub-pixel includes a storage capacitor 2, a polysilicon transistor 1, and at least one oxide transistor 3. The storage capacitor 2 includes a first electrode 18 and a second electrode 16 oppositely arranged, and the first electrode 18 is arranged on a side of the second electrode 16 away from the substrate 10.

Referring to FIG. 4, the second electrode 16 is arranged in a same layer as a gate electrode 15 of the polysilicon transistor 1. The oxide transistor 3 is disposed on a side of the first electrode 18 away from the substrate 10, and the first electrode 18 at least partially overlaps with an active layer 20 of the at least one oxide transistor 3 in a direction perpendicular to the substrate.

The first electrode is configured to access a power signal and also serves as a bottom gate of an overlapping oxide transistor. An oxide transistor at least partially overlapping with the first electrode in the direction perpendicular to the substrate is the overlapping oxide transistor.

A specific structure of the driving circuit used in the above sub-pixel is not limited, and for example, a 2T1C driving circuit, a 3T1C driving circuit or a 7T1C driving circuit may be used. In order to obtain better driving performance, a 7T1C driving circuit as shown in FIG. 2 may be adopted. For example, a polysilicon transistor may be used as a driving transistor T3, and an oxide transistor may be used as a switching transistor T1 or T2.

An active layer of the oxide transistor may be made of metal oxides such as IGZO (Indium Gallium Zinc Oxide) or ITZO (Indium Tin Zinc Oxide).

A type of the polysilicon transistor is not limited, and it may be a top-gate polysilicon transistor or a bottom-gate polysilicon transistor. In FIG. 4, which is illustrated by taking a top-gate polysilicon transistor as an example.

That the first electrode at least partially overlaps with an active layer of the at least one oxide transistor in a direction perpendicular to the substrate includes: the first electrode partially overlaps with the active layer of the at least one oxide transistor in the direction perpendicular to the substrate, and at this time, an orthographic projection of the first electrode on the substrate may partially overlap with the orthographic projection of the active layer of the at least one oxide transistor on the substrate; or the first electrode completely overlaps with the active layer of the at least one oxide transistor in the direction perpendicular to the substrate, and at this time, the orthographic projection of the active layer of the at least one oxide transistor on the substrate may be located within the orthographic projection of the first electrode on the substrate.

The overlapping oxide transistor may include a top gate, a bottom gate, a first electrode and a second electrode. A first electrode of the storage capacitor serves as the bottom gate and is electrically connected to a power signal line, which can play a role in protecting a channel and improving stability, and may also serve as a light shielding layer so as to further protect performance of the overlapping oxide transistor.

It should be noted that in general, a top gate and a bottom gate of a double-gate transistor are accessed with a same gate signal, but in the present disclosure, the top gate of the overlapping oxide transistor is accessed with a gate signal, and the bottom gate (i.e., the first electrode) is accessed with a power signal VDD (generally a 4.6 V DC voltage). Taking a structure shown in FIG. 15 as an example for performance test and referring to FIG. 15, an overlapping oxide transistor 200 includes a light shielding electrode 202, an IGZO active layer 205, a gate (G) electrode 206, a source (S) electrode 207 and a drain (D) electrode 208. Of course, this test structure also includes a glass substrate 201, a buffer layer 203 with stacked silicon oxide (with a thickness of 3000 Å) and silicon nitride (with a thickness of 500 Å), a GI gate insulating layer 204, a PVX passivation layer 210, a Resin flat layer 211 and a PDL defining layer 212. The light-shielding electrode serves as the bottom gate. As shown in FIG. 16, different DC voltages are input to the light shielding electrode and corresponding voltages are input to the gate (G) electrode, the source (S) electrode and the drain (D) electrode at the same time, and test results shown in Table 1 are obtained. Referring to Table 1, when a voltage of the light shielding electrode is 5 V, a threshold voltage Vth of the transistor is about −1.5 V. At this time, a turn-off voltage Vg1 of the transistor is −7 V, and the transistor may be turned off normally, which shows that the transistor with this structure has good performance and good switching performance, and may be applied to driving circuits.

TABLE 1

| | |
|---|---|
| Voltage Value of | Vth of Transistor |
| Light Shielding Electrode | (Vds: 15.1) |

| | | |
|---|---|---|
| −15 | V | 5.22 |
| −10 | V | 3.50 |
| −5 | V | 1.83 |
| 0 | V | 0.12 |
| 2 | V | −0.56 |
| 4 | V | −1.21 |
| 5 | V | −1.57 |
| 6 | V | −1.93 |
| 8 | V | −2.59 |
| 10 | V | −3.31 |
| 15 | V | −4.99 |

| | |
|---|---|
| ΔVth | 10.21 |

In the display base plate according to the present disclosure, the first electrode at least partially overlaps with the active layer of the at least one oxide transistor in the direction perpendicular to the substrate, and at the same time, the first electrode also serves as the bottom gate of the overlapping oxide transistor, so as to avoid additionally disposing a bottom gate of the overlapping oxide transistor, thereby greatly saving layout space, reducing a pitch between sub-pixels, and further greatly improving resolution while ensuring low power consumption.

Optionally, in order to improve performance of the transistor, the orthographic projection of the active layer of the at least one oxide transistor on the substrate is located within the orthographic projection of the first electrode on the substrate. Referring to FIG. 4, the orthographic projection F2 of the active layer 20 of the oxide transistor 3 on the substrate 10 is located within the orthographic projection F1 of the first electrode 18 on the substrate 10. In FIG. 4, which is illustrate by taking that the orthographic projection of the active layer of the oxide transistor on the substrate is located within the orthographic projection of the first electrode on the substrate as an example.

A specific structure of the active layer is not limited here. For example, the active layer of the oxide transistor may include a semiconductor part, a first-electrode contact part and a second-electrode contact part located at both ends of the semiconductor part. The first-electrode contact part is electrically connected to the first electrode, and the second-electrode contact part is electrically connected to the second electrode.

Further optionally, as shown in FIG. 4, an orthographic projection F3 of the second electrode 16 on the substrate 10 is located within the orthographic projection F1 of the first electrode 18 on the substrate 10, which may further save space and improve the resolution.

Optionally, in order to better provide a power signal to the first electrode, as shown in FIG. 4, the display base plate further includes a power line 31, and the first electrode 18 is electrically connected to the power line 31.

A specific location of the power line is not limited here. For example, the power line may be disposed in a separate layer or in a same layer as other structures.

Further optionally, in order to reduce a number of patternings and production cost, as shown in FIG. 4, the power line 31 is arranged in a same layer as the first electrode 32 and the second electrode 33 of the overlapping oxide transistor, that is, the power line and the first electrode and the second electrode of the overlapping oxide transistor may be formed at the same time through one patterning process.

An expression “arranged in the same layer” described above indicates preparing in one patterning process. The one patterning process refers to a process of forming a required layer structure through one exposure. The one patterning process includes mask, exposure, development, etching, stripping and other processes.

Optionally, in order to reduce design difficulty and reduce the number of patternings, as shown in FIG. 4, the polysilicon transistor is a top-gate polysilicon transistor, and the active layer 13 of the polysilicon transistor 1 is arranged between the substrate 10 and the gate 15 electrode of the polysilicon transistor 1.

Transistors may be divided into two types according to a position relationship of electrodes. One type is that a gate electrode is located below a source electrode and a drain electrode, which is called a bottom-gate thin film transistor; and the other is that the gate electrode is located above the source electrode and the drain electrode, which is called a top-gate thin film transistor.

Further optionally, in order to reduce a number of patternings and reduce production cost, as shown in FIG. 4, the first electrode 29 and the second electrode 30 of the polysilicon transistor 1 are arranged in a same layer as the first electrode 32 and the second electrode 33 of the overlapping oxide transistor, that is, the first electrode and the second electrode of the polysilicon transistor 1 and the first electrode and the second electrode of the overlapping oxide transistor may be formed at the same time through one patterning process.

It should be noted that, as shown in FIG. 4, if the display base plate further includes a power line 31, the power line 31, the first electrode 29 and the second electrode 30 of the polysilicon transistor are arranged in a same layer as the first electrode 32 and the second electrode 33 of the overlapping oxide transistor.

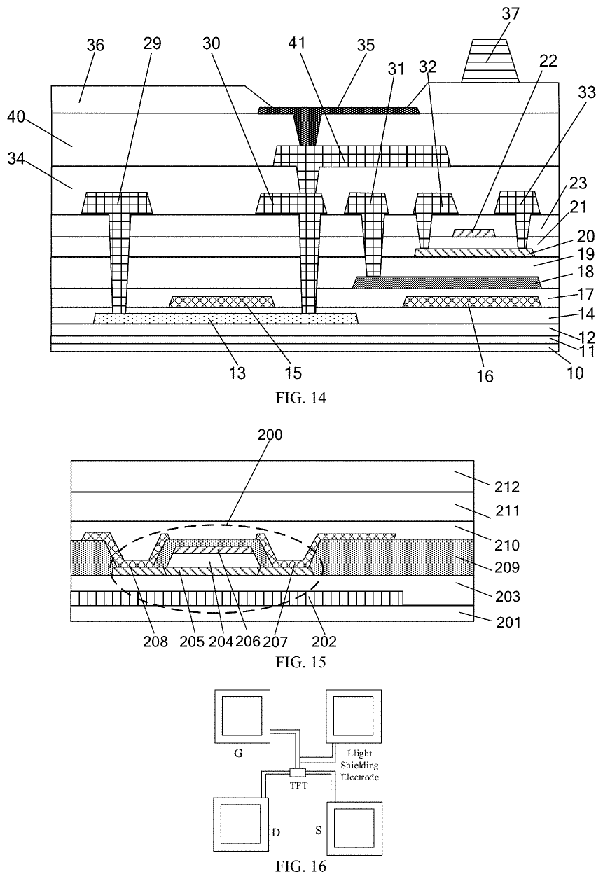

Further optionally, as shown in FIG. 4, the sub-pixel further includes an anode 35, and either the first electrode or the second electrode of the polysilicon transistor is electrically connected to the anode, thereby providing sufficient current to a light-emitting diode. In FIG. 4, which is illustrated by taking that the second electrode 30 of the polysilicon transistor is electrically connected to the anode 35 as an example. It should be noted that, as shown in FIG. 4, the anode 35 may be electrically connected to the second electrode 30 of the polysilicon transistor via a through hole throughout the first flat layer 34; or, as shown in FIG. 14, the anode may also be electrically connected to a connection electrode 41 via a through hole throughout through the second flat layer 40, and the connection electrode 41 is electrically connected to the second electrode 30 of the polysilicon transistor via a through hole throughout the first flat layer 34.

In one or more embodiments, in order to provide better driving performance, the polysilicon transistor is a P-type transistor and the oxide transistor is an N-type transistor.

In one or more embodiments, in order to improve expandability of the driving circuit, the sub-pixel may further include a single-gate oxide transistor, and an active layer of the single-gate oxide transistor does not overlap with the first electrode in the direction perpendicular to the substrate. At this time, the sub-pixel includes a plurality of transistors of different types, and sub-pixel driving circuits with different performances may be formed. A number of single-gate oxide transistors is not limited herein, which may be specifically determined according to actual requirements.

In one or more embodiments, referring to FIG. 2, the sub-pixel includes a first transistor T1, a second transistor T2, a third transistor T3, a fourth transistor T4, a fifth transistor T5, a sixth transistor T6 and a seventh transistor T7. The first transistor T1 and the second transistor T2 are the oxide transistors shown in FIG. 4, and the third transistor T3 is a polysilicon transistor, which may be the top-gate polysilicon transistor shown in FIG. 4.

Referring to FIG. 2, the display base plate further includes a power line ELVDD, a light-emitting control signal line EM, a data signal line Data, a reset control signal line Scan, and an initial signal line Vinit. The sub-pixel further includes a light-emitting diode LED. In FIG. 2, gate electrodes of all of the transistors are labeled G, first electrodes of all of the transistors are labeled S, and second electrodes of all of the transistors are labeled D.

Referring to FIG. 2, a gate electrode of the first transistor T1 is electrically connected to the reset control signal line Scan, a second electrode of the first transistor T1 is electrically connected to the initial signal line Vinit, a first electrode of the first transistor T1 and a first electrode of the second transistor T2 are electrically connected to a first node N1, a gate electrode of the third transistor T3 and a second electrode of the storage capacitor Cst are electrically connected to the first node N1, and a first electrode of the storage capacitor Cst is electrically connected to the power line ELVDD.

Referring to FIG. 2, a gate electrode of the second transistor T2 is electrically connected to the reset control signal line Scan, and a second electrode of the second transistor T2 is electrically connected to a third node N3, a first electrode of the third transistor T3 is electrically connected to a second node N2, and a second electrode of the third transistor T3 is electrically connected to the third node N3. A first electrode of the fourth transistor T4 is electrically connected to the second node N2, the second electrode of the fourth transistor T4 is electrically connected to the data signal line Data, a gate electrode of the fourth transistor T4 is electrically connected to the reset control signal line Scan. A second electrode of the fifth transistor T5 is electrically connected to the second node N2, a first electrode of the fifth transistor T5 is electrically connected to the power line ELVDD, and a gate electrode of the fifth transistor T5 is electrically connected to the light-emitting control signal line EM.

Referring to FIG. 2, a gate electrode of the sixth transistor T6 is electrically connected to the light-emitting control signal line EM, a first electrode of the sixth transistor T6 is electrically connected to the third node N3, and the second electrode of the sixth transistor T6 is electrically connected to a fourth node N4. A gate electrode of the seventh transistor T7 is electrically connected to the reset control signal line Scan, a first electrode of the seventh transistor T7 is electrically connected to the fourth node N4, and a second electrode of the seventh transistor T7 is electrically connected to the initial signal line Vinit. An anode of the light-emitting diode LED is electrically connected to the fourth node N4, and a cathode of the light-emitting diode LED is connected to ground ELVSS.

Orthographic projections of active layers of the first transistor and the second transistor on the substrate are both located within the orthographic projection of the first electrode on the substrate, and orthographic projections of active layers of other transistors on the substrate do not overlap with the orthographic projection of the first electrode on the substrate.

The first node N1, the second node N2, the third node N3 and the fourth node N4 described above are only for the convenience of describing the circuit structure, but not an actual circuit unit.

The fourth transistor, the fifth transistor, the sixth transistor and the seventh transistor may all be polysilicon transistors or oxide transistors, which is not limited herein.

A 7T1C driving circuit is adopted in the sub-pixel, and a driving principle of this driving circuit can be obtained by referring to related art, which will not be repeatedly described here again. The first electrode not only serves as an electrode of the storage capacitor, but also as bottom gates of the first transistor and the second transistor, so that it is possible to avoid additionally disposing the bottom gates of the first transistor and the second transistor, thereby greatly saving layout space and reducing the pitch between sub-pixels. The first transistor T1 and the second transistor T2 have a same structure as the oxide transistor shown in FIG. 4, and the third transistor T3 has a same structure as the polysilicon transistor shown in FIG. 4. Referring to FIG. 5, the first transistor T1 and the second transistor T2 overlap with the first electrode 18. Compared with FIG. 3, the first electrode 18 not only serves as an electrode of the storage capacitor, but also as the bottom gates of the first transistor and the second transistor, which can avoid additionally disposing the bottom gates of the first transistor and the second transistor and greatly save layout space. The pitch (spacing) between the sub-pixels shown in FIG. 5 is 42 μm, and a corresponding PPI is about 600. Compared with the structure shown in FIG. 3, the resolution is greatly improved while ensuring low power consumption.

It should be noted that, as shown in FIG. 4, the display base plate may further include an isolation layer 11, a first buffer layer 12, a first gate insulating layer 14, a second gate insulating layer 17, a second buffer layer 19, a third gate insulating layer 21, an interlayer dielectric layer 23, a first flat layer 34, a pixel defining layer 36, an anode 35 and a spacer 37, and of course, other structures may also be included. Only structures related to inventive points are introduced in embodiments of the present disclosure, and other structures may be obtained by referring to related art, which will not be repeatedly described here again.

A display panel including the display base plate described above is further provided in an embodiment of the disclosure.

The display panel may be a flexible display panel (also known as a flexible screen) or a rigid display panel (i.e., a display panel that cannot be bent), which is not limited herein. The display panel may be an OLED (Organic Light-Emitting Diode) display panel, a Micro LED display panel or a Mini LED display panel, and any products or components with display function including these display panels, such as televisions, digital cameras, mobile phones and tablet computers.

A method for preparing a display base plate is further provided in an embodiment of the disclosure, which includes a step S01.

In the step S01, a plurality of sub-pixels arranged in an array are formed on a substrate.

The step S01 in which a plurality of sub-pixels arranged in an array are formed on a substrate includes a step S10.

In the step S10, a storage capacitor, a polysilicon transistor and at least one oxide transistor are formed. The storage capacitor includes a first electrode and a second electrode oppositely arranged, and the first electrode is arranged at a side of the second electrode away from the substrate. The second electrode is arranged in the same layer as a gate electrode of the polysilicon transistor. The at least one oxide transistor is arranged on a side of the first electrode away from the substrate, and the first electrode at least partially overlaps with an active layer of the at least one oxide transistor in a direction perpendicular to the substrate. The first electrode is configured to access a power signal and also serves as a bottom gate of an overlapping oxide transistor. An oxide transistor at least partially overlapping with the first electrode in the direction perpendicular to the substrate is the overlapping oxide transistor.

In the display base plate formed by the preparation method described above, the first electrode at least partially overlaps with the active layer of the at least one oxide transistor in the direction perpendicular to the substrate, and at the same time, the first electrode also serve as the bottom gate of the overlapping oxide transistor, so as to avoid additionally disposing a bottom gate of the overlapping oxide transistor, thereby greatly saving layout space, reducing a pitch between sub-pixels, and further greatly improving resolution while ensuring low power consumption. The preparation method is simple and easy to realize.

Optionally, in order to reduce a number of patternings and reduce production cost, the step in which the storage capacitor and the polysilicon transistor are formed includes a step S20.

In the step S20, a second electrode of the storage capacitor and a gate electrode of the polysilicon transistor are formed by using one-step patterning process.

Optionally, in order to reduce the number of patternings and reduce production cost, the step in which the polysilicon transistor and the overlapping oxide transistor are formed includes a step S30.

In the step S30, a first electrode and a second electrode of the polysilicon transistor and a first electrode and a second electrode of the overlapping oxide transistor are formed by using one-step patterning process.

Taking the structure shown in FIG. 13 as an example, a preparation method is specifically described below.

The method includes following steps S101 to S108.

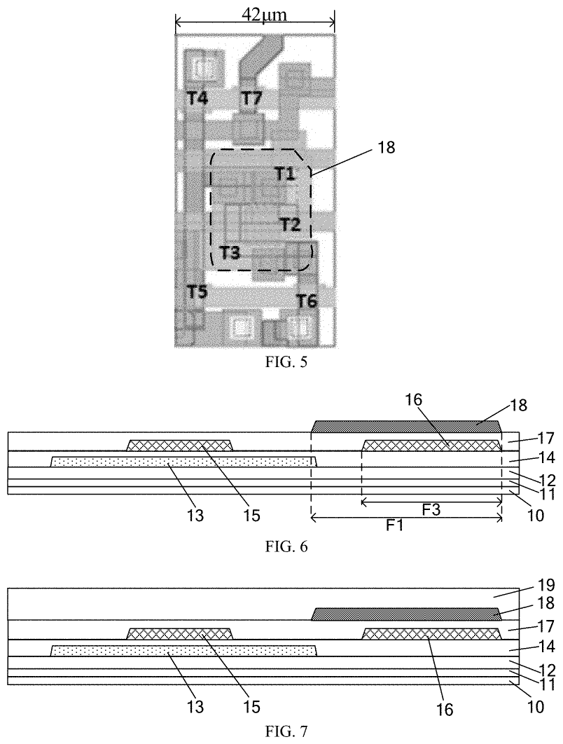

In the step S101, the isolation layer (Barrier) 11, the first buffer layer 12, the active layer 13 of the polysilicon transistor, the first gate insulating layer 14, the gate metal layer, the second gate insulating layer 17 and the first electrode 18 of the storage capacitor as shown in FIG. 6 are sequentially formed on the substrate 10. The gate metal layer includes the second electrode 16 of the storage capacitor and the gate electrode 15 of the polysilicon transistor, and the orthographic projection F3 of the second electrode 16 on the substrate 10 is located within the orthographic projection F1 of the first electrode 18 on the substrate 10.

The second electrode and the gate electrode of the polysilicon transistor are prepared by using one-step patterning process. The substrate described above may be a flexible substrate, such as a PI substrate, etc. Alternatively, it can also be a rigid substrate, such as a glass substrate. If the PI substrate is used, in order to provide better performance, an additional isolation film and PI film may be disposed between the substrate and the isolation layer sequentially.

The active layer of the polysilicon transistor may be made of a low-temperature polysilicon material. The first gate insulating layer and the second gate insulating layer may be made of silicon oxide or silicon nitride. The gate metal layer and the first electrode may be made of metals, such as copper and aluminum.

In the step S101, one mask is needed to form the active layer of the polysilicon transistor, one mask is needed to form the second electrode and the gate electrode of the polysilicon transistor, and one mask is needed to form the first electrode, totaling three masks.

In the step S102, a second buffer layer 19 as shown in FIG. 7 is deposited on the first electrode 18.

The second buffer layer is not only an insulating layer but also a gate insulating layer of the bottom gate (i.e. the second electrode). A material and a thickness thereof may be adjusted according to specific device characteristics, and silicon oxide with a thickness of 3000 Å is usually selected.

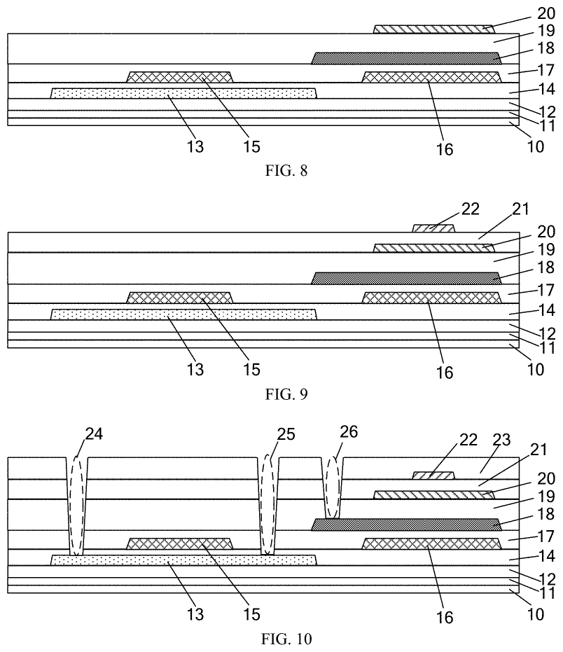

In the step S103, the active layer 20 of the oxide transistor as shown in FIG. 8 is formed on the second buffer layer 19.

The active layer may be made of a metal oxide material such as IGZO. In the step S103, one mask is needed to form the active layer of the oxide transistor.

In the step S104, the third gate insulating layer 21 and a gate electrode (i.e., top gate) 22 of the oxide transistor are formed as shown in FIG. 9. The third gate insulating layer 21 covers the active layer 20 of the oxide transistor.

In the step S104, one mask is needed to form the gate electrode of the oxide transistor.

In the step S105, as shown in FIG. 10, the interlayer dielectric layer 23 covering the gate electrode of the oxide transistor and a first through hole 24, a second through hole 25 and a third through hole 26 are formed.

The first through hole and the second through hole respectively penetrate through the interlayer dielectric layer, the third gate insulating layer, the second buffer layer, the second gate insulating layer and the first buffer layer. The third through hole penetrates through the interlayer dielectric layer, the third gate insulating layer and the second buffer layer. The first through hole is configured for electrically connecting the first electrode of the polysilicon transistor to the active layer of the polysilicon transistor. The second through hole is configured for electrically connecting the second electrode of the polysilicon transistor to the active layer of the polysilicon transistor; and the third through hole is configured for electrically connecting the power signal line to the first electrode.

In the step S105, the first through hole and the second through hole are firstly formed by etching, which is then subjected to HF (hydrogen fluoride) cleaning, and then the third through hole is formed. One mask is needed to form the first through hole and the second through hole, and one mask is needed to form the third through hole, totaling two masks.

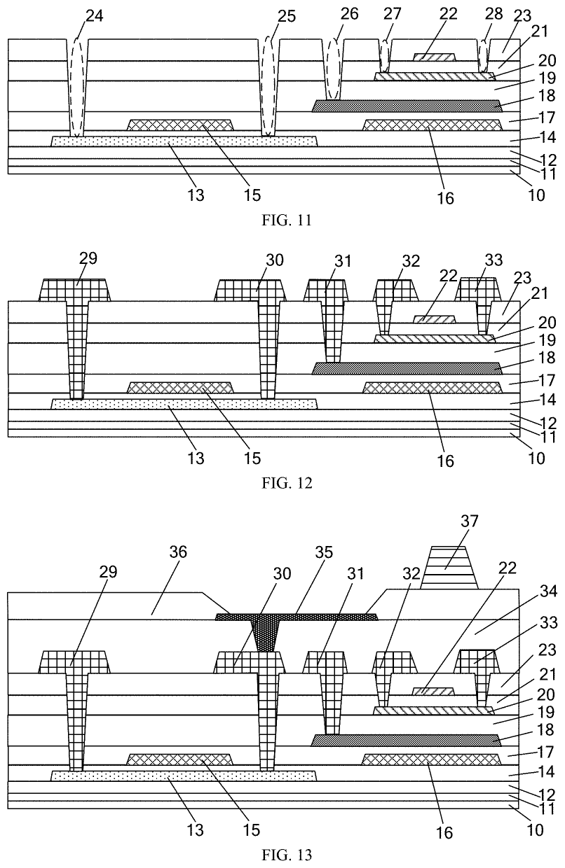

In the step S106, the fourth through hole 27 and the fifth through hole 28 as shown in FIG. 11 are formed.

The fourth through hole and the fifth through hole respectively penetrate through the third gate insulating layer and the second buffer layer, the fourth through hole is configured for electrically connecting the first electrode of the oxide transistor to the active layer of the oxide transistor, and the fifth through hole is configured for electrically connecting the second electrode of the oxide transistor to the active layer of the oxide transistor. In the step S106, one mask is needed to form the fourth through hole and the fifth through hole.

In the step S107, a source-drain metal layer is formed. The source-drain metal layer includes the first electrode 29 and the second electrode 30 of the polysilicon transistor, the power signal line ELVDD line 31, and the first electrode 32 and the second electrode 33 of the oxide transistor as shown in FIG. 12.

The first electrode and the second electrode of the polysilicon transistor are electrically connected to the active layer of the polysilicon transistor through the first through hole and the second through hole respectively, the power signal line ELVDD is electrically connected to the first electrode through the third through hole, and the first electrode and the second electrode of the oxide transistor are electrically connected to the active layer of the oxide transistor through the fourth through hole and the fifth through hole respectively. In the step S107, one mask is needed to form the fourth through hole and the fifth through hole.

In the step S108, the first flat layer 34 covering the source-drain metal layer, the anode 35, the pixel defining layer 36 and the spacer (PS)37 as shown in FIG. 13 are formed.

The flat layer includes a sixth through hole, and the anode is electrically connected to the second electrode of the polysilicon transistor through the sixth through hole. In the step S108, one mask is needed to form the sixth through hole, one mask is needed to form the anode, one mask is needed to form the pixel defining layer, and one mask is needed to form the spacer, totaling four masks.

In the preparation method described above, 3 masks are used in the step S101, 1 mask is used in the step S103, 1 mask is used in the step S104, 2 masks are used in the step S105, 1 mask is used in the step S106, 1 mask is used in the step S107 and 4 masks are used in the step S108, totaling 13 masks.

The preparation method is simple and easy to realize, and a display base plate with a large resolution is formed while keeping a number of the original composition processes unchanged.

It should be noted that related structural description of the display base plate involved in the embodiment of the present disclosure can refer to the previous embodiments, which will not be repeatedly described here again.

Reference to “one embodiment”, “an embodiment” or “one or more embodiments” herein means that a specific feature, structure or characteristic described in connection with embodiments is included in at least one embodiment of the present disclosure. In addition, it is noted that an example of a word “in one embodiment” here do not necessarily refer to a same embodiment.

In the specification provided here, numerous specific details are set forth. However, it can be understood that the embodiments of the present disclosure can be practiced without these specific details. In some instances, well-known methods, structures and techniques have not been shown in detail in order not to obscure understanding of this specification.

Finally, it should be noted that the above embodiments are only intended to illustrate technical solutions of the present disclosure, but not to limit it. Although the present disclosure has been described in detail with reference to the foregoing embodiments, it should be understood by ordinary skilled in the art that modifications can be made to the technical solutions described in the foregoing embodiments, or equivalent substitutions can be made to some technical features thereof. These modifications or substitutions do not make essence of corresponding technical solutions depart from the spirit and scope of the technical solutions of the embodiments of the present disclosure.

1. A display base plate, comprising a substrate and a plurality of sub-pixels arranged in an array at one side of the substrate;
each of the plurality of sub-pixels comprises a storage capacitor, a polysilicon transistor and at least one oxide transistor; wherein the storage capacitor comprises a first electrode and a second electrode oppositely arranged, and the first electrode is arranged at a side of the second electrode away from the substrate;
the second electrode being arranged in a same layer as a gate electrode of the polysilicon transistor, the at least one oxide transistor being arranged on a side of the first electrode away from the substrate, and the first electrode at least partially overlapping with an active layer of the at least one oxide transistor in a direction perpendicular to the substrate; and
the first electrode being configured to access a power signal and further serving as a bottom gate of an overlapping oxide transistor, wherein an oxide transistor at least partially overlapping with the first electrode in the direction perpendicular to the substrate is the overlapping oxide transistor.

2. The display base plate according to claim 1, wherein an orthographic projection of the active layer of the at least one of the oxide transistors on the substrate is located within an orthographic projection of the first electrode on the substrate.

3. The display base plate according to claim 2, wherein an orthographic projection of the second electrode on the substrate is located within the orthographic projection of the first electrode on the substrate.

4. The display base plate according to claim 1, wherein the display base plate further comprises a power line, and the first electrode is electrically connected to the power line.

5. The display base plate according to claim 4, wherein the power line is arranged in the same layer as a first electrode and a second electrode of the overlapping oxide transistor.

6. The display base plate according to claim 1, wherein the polysilicon transistor is a top-gate polysilicon transistor, and the active layer of the polysilicon transistor is arranged between the substrate and the gate electrode of the polysilicon transistor.

7. The display base plate according to claim 6, wherein a first electrode and a second electrode of the polysilicon transistor are arranged in the same layer as a first electrode and a second electrode of the overlapping oxide transistor.

8. The display base plate according to claim 7, wherein the sub-pixel further comprises an anode, and either the first electrode or the second electrode of the polysilicon transistor is electrically connected to the anode.

9. The display base plate according to claim 1, wherein the polysilicon transistor is a P-type transistor and the oxide transistor is an N-type transistor.

10. The display base plate according to claim 1, wherein the sub-pixel further comprises a single-gate oxide transistor, and an active layer of the single-gate oxide transistor does not overlap with the first electrode in the direction perpendicular to the substrate.

11. The display base plate according to claim 1, wherein the sub-pixel further comprises a first transistor, a second transistor, a third transistor, a fourth transistor, a fifth transistor, a sixth transistor and a seventh transistor; and the first transistor and the second transistor are the oxide transistors and the third transistor is the polysilicon transistor;
the display base plate further comprises a power line, a light-emitting control signal line, a data signal line, a reset control signal line and an initial signal line; and the sub-pixel further comprises a light-emitting diode;
a gate electrode of the first transistor is electrically connected to the reset control signal line, a second electrode of the first transistor is electrically connected to the initial signal line, a first electrode of the first transistor and a first electrode of the second transistor are electrically connected to a first node, a gate electrode of the third transistor and a second electrode of the storage capacitor are electrically connected to the first node, and a first electrode of the storage capacitor is electrically connected to the power line;
a gate electrode of the second transistor is electrically connected to the reset control signal line, and a second electrode of the second transistor is electrically connected to a third node, a first electrode of the third transistor is electrically connected to a second node, and a second electrode of the third transistor is electrically connected to the third node, a first electrode of the fourth transistor is electrically connected to the second node, the second electrode of the fourth transistor is electrically connected to the data signal line, a gate electrode of the fourth transistor is electrically connected to the reset control signal line, a second electrode of the fifth transistor is electrically connected to the second node, a first electrode of the fifth transistor is electrically connected to the power line, and a gate electrode of the fifth transistor is electrically connected to the light-emitting control signal line; and
a gate electrode of the sixth transistor is electrically connected to the light-emitting control signal line, a first electrode of the sixth transistor is electrically connected to the third node, and the second electrode of the sixth transistor is electrically connected to a fourth node, a gate electrode of the seventh transistor is electrically connected to the reset control signal line, a first electrode of the seventh transistor is electrically connected to the fourth node, and a second electrode of the seventh transistor is electrically connected to the initial signal line, an anode of the light-emitting diode is electrically connected to the fourth node, and a cathode of the light-emitting diode is connected to ground;
wherein orthographic projections of active layers of the first transistor and the second transistor on the substrate are both located within an orthographic projection of the first electrode on the substrate, and orthographic projections of active layers of other transistors on the substrate do not overlap with the orthographic projection of the first electrode on the substrate.

12. A display panel comprising the display base plate according to claim 1.

13. A method for manufacturing the display base plate according to claim 1, comprising:
forming the plurality of sub-pixels arranged in the array on the substrate;
wherein forming the plurality of sub-pixels arranged in the array on the substrate comprises:
forming the storage capacitor, the polysilicon transistor and at least one oxide transistor; wherein the storage capacitor comprises the first electrode and the second electrode oppositely arranged, the first electrode is arranged at the side of the second electrode away from the substrate, the second electrode is arranged in the same layer as the gate electrode of the polysilicon transistor; the at least one oxide transistor is arranged on the side of the first electrode away from the substrate, and the first electrode at least partially overlaps with the active layer of the at least one oxide transistor in the direction perpendicular to the substrate; and the first electrode is configured to access the power signal and further serves as the bottom gate of the overlapping oxide transistor, wherein the oxide transistor at least partially overlapping with the first electrode in the direction perpendicular to the substrate is the overlapping oxide transistor.

14. The method according to claim 13, wherein forming the storage capacitor and the polysilicon transistor comprises:
forming a second electrode of the storage capacitor and a gate electrode of the polysilicon transistor by using one-step patterning process.

15. The method according to claim 13, wherein forming the polysilicon transistor and the overlapping oxide transistor comprises:
forming a first electrode and a second electrode of the polysilicon transistor and a first electrode and a second electrode of the overlapping oxide transistor by using one-step patterning process.

16. The display panel according to claim 12, wherein an orthographic projection of the active layer of the at least one of the oxide transistors on the substrate is located within an orthographic projection of the first electrode on the substrate.

17. The display panel according to claim 16, wherein an orthographic projection of the second electrode on the substrate is located within the orthographic projection of the first electrode on the substrate.

18. The display panel according to claim 12, wherein the display base plate further comprises a power line, and the first electrode is electrically connected to the power line.

19. The display panel according to claim 18, wherein the power line is arranged in the same layer as a first electrode and a second electrode of the overlapping oxide transistor.

20. The display panel according to claim 12, wherein the polysilicon transistor is a top-gate polysilicon transistor, and the active layer of the polysilicon transistor is arranged between the substrate and the gate electrode of the polysilicon transistor.
